(19) United States
(12) Patent Application Publication
(10) Pub. No.: US 2025/0017084 A1
(43) Pub. Date: Jan. 9, 2025

(54) DISPLAY APPARATUS COMPRISING ENCAPSULATION FILM AND ENCAPSULATION FILM HAVING OXYGEN BARRIER LAYER

(71) Applicant: LG Display Co., Ltd., Seoul (KR)

(72) Inventors: SeongYong UHM, Paju-si (KR); SangGil DOH, Ansan-si (KR); Kyuwan LEE, Ansan-si (KR); Dohyung KIM, Paju-si (KR); Tae-Kyung KIM, Paju-si (KR); MinHo OH, Paju-si (KR)

(73) Assignee: LG Display Co., Ltd., Seoul (KR)

(21) Appl. No.: 18/410,690

(22) Filed: Jan. 11, 2024

(30) Foreign Application Priority Data
Jan. 19, 2023 (KR) 10-2023-0007907
Nov. 16, 2023 (KR) 10-2023-0159049

(51) Int. Cl. H10K 59/80

(52) U.S. Cl. CPC H10K 59/874; H10K 59/873

(57) ABSTRACT

An encapsulation film including an adhesive layer and an oxygen barrier layer on the adhesive layer is provided. The oxygen barrier layer includes binder resin and oxygen collecting particles dispersed in the binder resin. The oxygen collecting particles includes a first metal oxide that includes a crystal structure consisting of first metal sites and oxygen sites, where the crystal structure is in an oxygen deficiency state. A display apparatus including the encapsulation film is disclosed herein.

### CROSS-REFERENCE TO RELATED APPLICATIONS

This application claims the priority of Korean Patent Application No. 10-2023-0007907 filed on Jan. 19, 2023 and Korean Patent Application No. 10-2023-0159049 filed on Nov. 16, 2023, the disclosures of which are incorporated herein by reference.

### BACKGROUND

### 1. Technical Field

The present disclosure relates to a display apparatus including an encapsulation film and an encapsulation film having an oxygen barrier layer with desirable oxygen blocking properties.

### 2. Description of the Related Art

Recently, a flat display apparatus or a flexible display apparatus is used as a display apparatus. Among them, an organic light emitting display apparatus, which is a self-luminous display apparatus, has advantages such as a wide viewing angle, desirable contrast characteristic, and a rapid response speed. In addition, the organic light emitting display apparatus may be easily applied to the flexible display apparatus.

The organic light emitting display apparatus includes a plurality of organic light emitting diodes. The organic light emitting diode includes an anode electrode, a light emitting layer, and a cathode electrode. When a high potential voltage is applied to the anode electrode and a low potential voltage is applied to the cathode electrode, holes move from the anode electrode to the light emitting layer and electrons move from the cathode electrode to the light emitting layer. When the holes and electrons are combined in the light emitting layer, an exciton is formed in an excitation process, and light is generated by the energy from the exciton. The organic light emitting display device electrically controls the amount of light generated from the light emitting layers in the plurality of organic light emitting diodes to display an image.

The organic light emitting display apparatus has the above-mentioned advantages, however, it may be vulnerable to moisture and oxygen. To solve these problems, various methods capable of preventing or reducing moisture and oxygen permeating into the organic light emitting display apparatus from the outside are being studied.

Various encapsulation methods have been developed as a method for preventing or reducing moisture and oxygen penetrating from the outside into the organic light emitting display apparatus. For example, the encapsulation method may include a thin film encapsulation method and a method of using an encapsulation film. The thin film encapsulation method is a method for preventing or reducing moisture and oxygen by stacking an organic layer and an inorganic layer on a display panel. The encapsulation film is a film structure attached to the display panel and configured to block moisture and oxygen.

### SUMMARY

The present disclosure has been made in view of the above problems. An object according to one aspect of the present disclosure is to provide a display apparatus with an encapsulation film having desirable oxygen blocking properties and effectively preventing or reducing oxygen from permeating into the display apparatus from the outside.

Another object of the present disclosure is to provide an encapsulation film having desirable oxygen blocking ability by including an oxygen barrier layer.

Yet another object of the present disclosure is to provide an encapsulation film that selectively discolors an oxygen collection portion, and thus, enables the determination of a degree of contamination due to oxygen, and a display apparatus including the same.

To achieve these and other advantages and in accordance with objects of the disclosure, as embodied and broadly described herein, a display apparatus includes a display panel, and an encapsulation film on the display panel, the encapsulation film including an adhesive layer, and an oxygen barrier layer on the adhesive layer, the oxygen barrier layer including binder resin and oxygen collecting particles dispersed in the binder resin, the oxygen collecting particles including a first metal oxide that includes a crystal structure consisting of first metal sites and oxygen sites, where the crystal structure is in an oxygen deficiency state. The first metal oxide may be in a reduced state.

A bond energy of a first metal-oxygen bond may be greater than a bond energy of an oxygen-oxygen bond in an oxygen molecule O₂.

The bond energy of the first metal-oxygen bond may be greater than 498 kJ.

The bond energy of the first metal-oxygen bond may be in a range of 550 kJ to 850 kJ.

The first metal oxide may include at least one metal selected from actinium Ac, boron B, barium Ba, berkelium Bk, cerium Ce, curium Cm, dysprosium Dy, erbium Er, gadolinium Gd, germanium Ge, hafnium Hf, holmium Ho, lanthanum La, lawrencium Lr, ruthenium Ru, niobium Nb, neodymium Nd, neptunium Np, zirconium Zr, and osmium Os.

The first metal oxide may include a cerium oxide represented by Chemical Formula 1,

CeOₓ [Chemical Formula 1]
where, 1.5<x<2.

The first metal oxide may be the cerium oxide. The crystal structure may consist of: cerium at the first metal sites, oxygen at the oxygen sites, and at least one vacant oxygen site.

The oxygen barrier layer may include the oxygen collecting particles at a content of 0.5 to 50 wt % based on a total weight of the oxygen barrier layer.

The oxygen barrier layer may have a thickness of 5 to 50 μm.

The oxygen barrier layer may have a thickness of 5 to 20 μm.

The oxygen collecting particles may have an average particle diameter of 0.5 to 10 μm.

The oxygen collecting particles may have an average particle diameter of 1 to 3 μm.

The binder resin may include at least one binder selected from an acrylic polymer, an olefin-based polymer, an ester-based polymer, a silicon-based polymer, an amide-based polymer, a rubber-based polymer, and a copolymer thereof.

The oxygen barrier layer may have a blue color having an ‘x’ value in a range of 0.25 to 0.29 and a ‘y’ value in a range of 0.25 to 0.29, based on CIE 1931 xy color coordinates.

The oxygen barrier layer may be configured to change from the blue color to a white color having the ‘x’ value in a range of 0.31 to 0.35 and the ‘y’ value is in a range of 0.32 to 0.36, based on the CIE 1931 xy color coordinates, when the oxygen barrier layer is in contact with oxygen molecule.

The encapsulation film may further include a moisture barrier layer disposed on the oxygen barrier layer, and the moisture barrier layer may include adhesive resin and absorbent dispersed in the adhesive resin.

The absorbent may include a second metal oxide, the second metal oxide may include a second metal and oxygen, and a bond energy of a second metal-oxygen bond in the second metal oxide may be smaller than a bond energy between an oxygen-oxygen bond in an oxygen molecule.

The second metal oxide may include calcium oxide CaO.

A central portion of the oxygen barrier layer may have a color having an ‘x’ value in a range of 0.25 to 0.29 and a ‘y’ value in a range of 0.25 to 0.29, based on CIE 1931 xy color coordinates, and a portion positioned within at least 300 μm from an edge end of the oxygen barrier layer may have a color having the ‘x’ value in a range of 0.31 to 0.35 and the ‘y’ value in a range of 0.32 to 0.36, based on CIE 1931 xy color coordinates, wherein the central portion of the oxygen barrier layer may be positioned within 50% of a distance between a center point and an edge end of the oxygen barrier layer from the center point of the oxygen barrier layer.

In another aspect of the present disclosure, an encapsulation film includes an adhesive layer, and an oxygen barrier layer on the adhesive layer, the oxygen barrier layer including binder resin, and oxygen collecting particles dispersed in the binder resin, the oxygen collecting particles including a metal oxide that includes a crystal structure consisting of first metal sites and oxygen sites, where the crystal structure is in an oxygen deficiency state.

The first metal oxide may be in a reduced state.

A bond energy of a first metal-oxygen bond may be greater than a bond energy of an oxygen-oxygen bond in an oxygen molecule O₂.

The bond energy of the first metal-oxygen bond may be greater than 498 kJ.

The first metal oxide may include a cerium oxide represented by Chemical Formula 1,

CeOₓ [Chemical Formula 1]
where, 1.5<x<2.

The first metal oxide may be the cerium oxide. The crystal structure may consist of: cerium at the first metal sites, oxygen at the oxygen sites, and at least one vacant oxygen site.

The oxygen barrier layer may have a blue color having an ‘x’ value in a range of 0.25 to 0.29 and a ‘y’ value in a range of 0.25 to 0.29, based on CIE 1931 xy color coordinates.

The oxygen barrier layer may be configured to change from the blue color to a white color having the ‘x’ value in a range of 0.31 to 0.35 and the ‘y’ value in a range of 0.32 to 0.36, based on CIE 1931 xy color coordinates, when the oxygen barrier layer is in contact with oxygen molecule.

The encapsulation film may further comprise a moisture barrier layer disposed on the oxygen barrier layer, wherein the moisture barrier layer may include adhesive resin and absorbent dispersed in the adhesive resin.

The absorbent may include a second metal oxide, the second metal oxide may include a second metal and oxygen, and a bond energy of a second metal-oxygen bond in the second metal oxide may be smaller than a bond energy of an oxygen-oxygen bond in an oxygen molecule.

The absorbent may include calcium oxide CaO.

In another aspect of the present disclosure, an encapsulation film includes an adhesive layer, and an oxygen barrier layer on the adhesive layer, the oxygen barrier layer including binder resin, and oxygen collecting particles dispersed in the binder resin, the oxygen collecting particles including a metal oxide that includes a crystal structure and that is represented by Chemical Formula 1:

CeOₓ [Chemical Formula 1]
where 1.5<x<2.

In the Chemical Formula 1, 1.55≤ x≤1.95.

In addition to the effects of the present disclosure as mentioned above, additional advantages and features of the present disclosure will be clearly understood by those skilled in the art from the description of the present disclosure.

It is to be understood that both the foregoing general description and the following detailed description of the present disclosure are merely by way of example and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 is a schematic diagram of a display apparatus according to an example embodiment of the present disclosure.

FIG. 2 is a circuit diagram of one pixel of the display apparatus according to the example embodiment illustrated in FIG. 1.

FIG. 3 is a partial cross-sectional view of a pixel of a display apparatus according to an example embodiment of the present disclosure.

FIG. 4 is a partial cross-sectional view of a display apparatus according to an example embodiment of the present disclosure.

FIG. 5 is a schematic cross-sectional view of an encapsulation film according to an example embodiment of the present disclosure.

FIG. 6A is an example of a crystal structure of a metal oxide in an oxygen saturation state.

FIG. 6B is an example of a crystal structure of a metal oxide in an oxygen deficiency state.

FIG. 7 is a schematic diagram of a crystal structure of cerium oxide according to an example embodiment of the present disclosure.

FIGS. 8A and 8B are X-ray diffraction analysis graphs of cerium oxide.

FIG. 9 is the CIE 1931 color coordinates in which the horizontal axis corresponds to the ‘x’ values and the vertical axis corresponds to the ‘y’ values.

FIG. 10 is a schematic cross-sectional view of an encapsulation film according to another example embodiment of the present disclosure.

FIG. 11 is a schematic cross-sectional view of an encapsulation film according to another example embodiment of the present disclosure.

FIG. 12 is a plan view of an oxygen barrier layer according to an example embodiment of the present disclosure.

FIG. 13 is a photograph of a portion of an oxygen barrier layer.

FIG. 14A is a photograph that shows the occurrence of dark spots in a display apparatus according to a reference embodiment.

FIGS. 14B and 14E are each a photograph that shows the occurrence of dark spots in a display apparatus according to a comparative embodiment.

FIGS. 14C and 14D are each a photograph that shows the occurrence of dark spots or the lack of thereof in a display apparatus according to an example embodiment of the present disclosure.

### DETAILED DESCRIPTION

Reference will now be made in detail to some of the examples and embodiments of the disclosure illustrated in the accompanying drawings. Wherever possible, the same reference numbers will be used throughout the drawings to refer to the same or like parts.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and may be embodied in various different forms. Thus, these example embodiments are set forth only to make the present disclosure sufficiently complete, and to assist those skilled in the art to fully understand the scope of the present disclosure. The protected scope of the present disclosure is defined by claims and their equivalents.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. The same or similar elements are designated by the same reference numerals throughout the specification unless otherwise specified.

Further, where the detailed description of the relevant known steps and elements may obscure an important point of the present disclosure, a detailed description of such known steps and elements may be omitted.

In the present specification, where the terms “comprise,” “have,” “include,” and the like are used, one or more other elements may be added unless the term, such as “only,” is used.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing an element or numerical value, the element or the numerical value is to be construed as including an error or tolerance range even where no explicit description of such an error or tolerance range is provided.

In the description of the various embodiments of the present disclosure, where positional relationships are described, for example, where the positional relationship between two parts is described using “on,” “above,” “below,” “beneath”, and “next,” or the like, one or more other parts may be located between the two parts unless a more limiting term, such as “just,” “immediate(ly),” “direct(ly),” or “close(ly)” is used.

Spatially relative terms, such as “below”, “beneath”, “lower”, “above”, “upper” or the like, may be used to describe a position of one element or component and relative to another element or component as illustrated in the drawing. The spatially relative terms are to be understood as terms including different orientations of the device in use or in operation in addition to the orientation depicted in the drawings. For example, if the device illustrated in the drawing is turned over, the element described as “below” or “beneath” other elements may be orientated to be “above” other element(s). Accordingly, the term “below,” which is an example term, may include all orientations in which the element or component is below or above the other element or component. In the same manner, the term “above” or “on” may include both orientations in which the element or component is above or below the other element or component.

In descriptions of temporal relationships, for example, temporal precedent relationships between two events such as “after”, “subsequent to”, “before”, “next.” etc., another event may occur therebetween unless a more limiting term, “just,” “immediate(ly),” or “direct(ly)” (“directly after”, “directly subsequent”, “directly before”) is indicated.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

An expression such as “at least one of” when preceding a list of elements may modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The features of the various embodiments of the present disclosure may be partially or overall combined with each other, and may be variously inter-operated with each other and driven technically as those skilled in the art can sufficiently understand. The embodiments may be implemented independently of each other and may be implemented together in an co-dependent relationship.

For convenience of description, a scale in which each of elements is illustrated in the accompanying drawings may differ from an actual scale. Thus, the illustrated elements are not limited to the specific scale in which they are illustrated in the drawings.

Hereinafter, a display apparatus according to the present disclosure will be described with reference to the accompanying drawings.

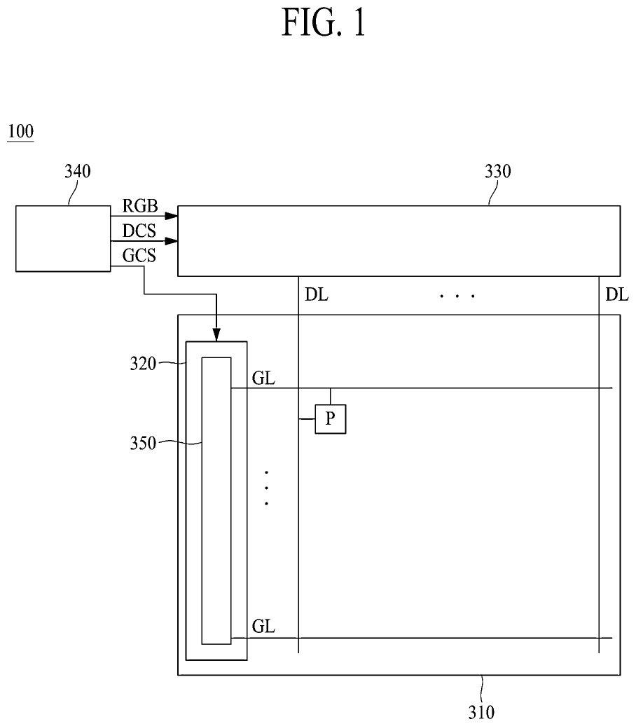

FIG. 1 is a schematic diagram of a display apparatus 100 according to an example embodiment of the present disclosure.

The display apparatus 100 according to an example embodiment of the present disclosure may include a display panel 310, a gate driver 320, a data driver 330, and a controller 340.

In some example embodiments of the present disclosure, gate lines GL and data lines DL are arranged on the display panel 310, and each pixel P is arranged in an intersection region between the gate lines GL and the data lines DL. An image is displayed by the driving of the pixel P.

The controller 340 controls the gate driver 320 and the data driver 330.

For example, the controller 340 outputs a gate control signal GCS for controlling the gate driver 320. The controller 340 may output a data control signal DCS for controlling the data driver 330 by using a signal supplied from an external system (not shown). In addition, the controller 340 samples input image data inputted from the external system, rearranges the sampled input image data, and supplies the rearranged digital image data RGB to the data driver 330.

The gate control signal GCS includes a gate start pulse GSP, a gate shift clock GSC, a gate output enable signal GOE, a start signal Vst, and a gate clock GCLK. In some example embodiments of the present disclosure, control signals for controlling the shift register 350 may be included in the gate control signal GCS.

For example, the data control signal DCS includes a source start pulse SSP, a source shift clock signal SSC, a source output enable signal SOE, a polarity control signal POL, and the like.

The data driver 330 supplies a data voltage to the data lines DL of the display panel 310. For example, the data driver 330 converts the image data RGB input from the controller 340 into an analog data voltage and supplies the data voltage to the data lines DL.

The gate driver 320 may include a shift register 350.

The shift register 350 sequentially supplies gate pulses to the gate lines GL during one frame by using the start signal and the gate clock transmitted from the controller 340. Herein, one frame refers to a period in which one image is output through the display panel 310. The gate pulse has a turn-on voltage capable of turning on a switching device (thin film transistor) arranged in the pixel P.

In some example embodiments of the present disclosure, the shift register 350 supplies a gate-off signal capable of turning off the switching device to the gate line GL during a remaining period in which the gate pulse is not supplied in one frame. The gate pulse and the gate-off signal together referred to as a scan signal.

According to an example embodiment of the present disclosure, the gate driver 320 may be mounted on the display panel 310. The structure in which the gate driver 320 is directly mounted on the display panel 310 is referred to as a gate-in-panel GIP structure.

The gate driver 320 may include a plurality of thin film transistors. The plurality of thin film transistors may be arranged in the shift register 350.

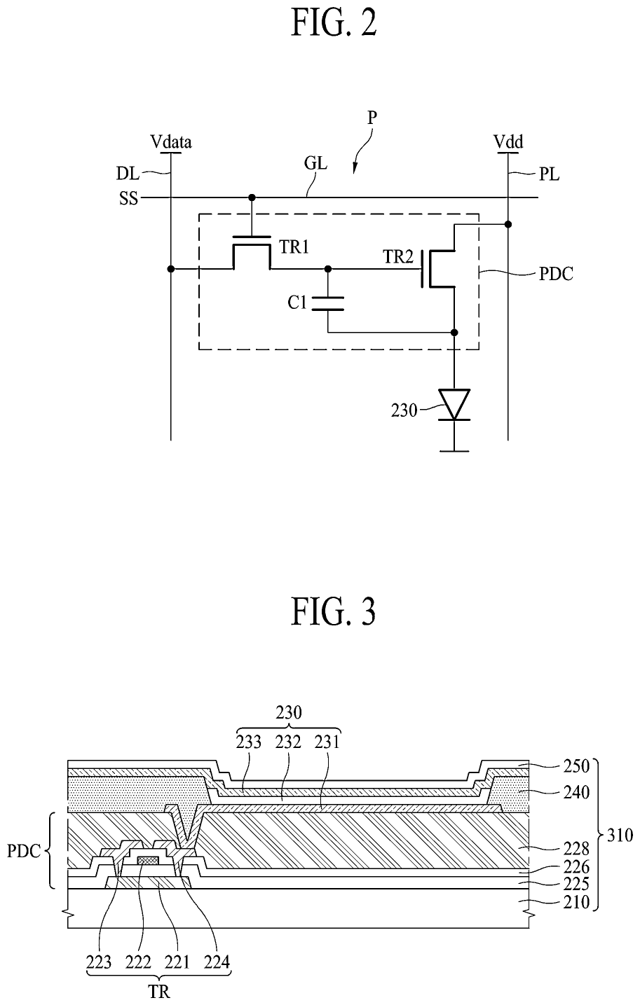

FIG. 2 is a circuit diagram of one pixel of the display apparatus according to the example embodiment illustrated in FIG. 1.

The circuit diagram as illustrated in the example embodiment of FIG. 2 is an equivalent circuit diagram of the pixel P of the display apparatus 100 including an organic light emitting device OLED as a display device 230. The pixel P includes the display device 230 and a pixel driver PDC for driving the display device 230.

As illustrated in FIG. 2, the display apparatus 100 according to an example embodiment of the present disclosure includes the pixel driver PDC and the display device 230 connected to the pixel driver PDC. The pixel driver PDC may include a first thin film transistor TR1 and a second thin film transistor TR2.

FIG. 2 illustrates the pixel driver PDC having the first thin film transistor TR1 corresponding to a switching transistor and the second thin film transistor TR2 corresponding to a driving transistor.

The first thin film transistor TR1 is connected to the gate line GL and the data line DL, and the first thin film transistor TR1 is turned-on or turned-off by the scan signal SS supplied through the gate line GL.

The data line DL provides the data voltage Vdata to the pixel driver PDC, and the first thin film transistor TR1 controls an application of the data voltage Vdata.

A driving power line PL provides a driving voltage Vdd to the display device 230, and the second thin film transistor TR2 controls the driving voltage Vdd. The driving voltage Vdd is a pixel driving voltage for driving the organic light emitting device OLED which is the display device 230.

When the first thin film transistor TR1 is turned-on by the scan signal SS applied through the gate line GL from the gate driver 320, the data voltage Vdata supplied through the data line DL is supplied to a gate electrode of the second thin film transistor TR2 connected to the display device 230. The data voltage Vdata is charged in a capacitor CI formed between or disposed between gate and source electrodes of the second thin film transistor TR2. The capacitor CI as illustrated in the example embodiment of FIG. 2 is a storage capacitor formed between or disposed between the gate and source electrodes of the second thin film transistor TR2.

As illustrated in FIG. 2, the gate electrode of the second thin film transistor TR2 is connected to a drain electrode of the first thin film transistor TR1. Therefore, the capacitor CI as illustrated in the example embodiment of FIG. 2 may be formed between or disposed between the drain electrode of the first thin film transistor TR1 and the source electrode of the second thin film transistor TR2.

The amount of current supplied to the organic light emitting device OLED, which is the display device 230, is controlled through the second thin film transistor TR2 according to the data voltage Vdata, whereby it is possible to control a grayscale of light output from the display device 230.

FIG. 3 is a partial cross-sectional view of the pixel P in the display apparatus 100 according to an example embodiment of the present disclosure.

As illustrated in FIG. 3, the display apparatus 100 according to an example embodiment of the present disclosure may include a base substrate 210, a thin film transistor TR, and a display device 230.

The display apparatus 100 according to an example embodiment of the present disclosure includes the thin film transistor TR on the base substrate 210, a planarization layer 228 on the thin film transistor TR, and the display device 230 disposed on the planarization layer 228 and connected to the thin film transistor TR. In FIG. 3, a portion including the thin film transistor TR and the planarization layer 228 corresponds to the pixel driver PDC illustrated in the example embodiment of FIG. 2. Also, the thin film transistor TR illustrated in the example embodiment of FIG. 3 is a driving transistor, which corresponds to the second thin film transistor TR2 illustrated in the example embodiment of FIG. 2.

The base substrate 210 may include a display area and a non-display area surrounding the display area. The base substrate 210 may be a flexible substrate or a rigid substrate. The base substrate 210 may include a plastic material or a glass material. For example, the base substrate of the plastic material may be a polyimide substrate.

A buffer layer (not shown) may be disposed on the base substrate 210. The buffer layer may be disposed to cover an entire surface of the base substrate. The buffer layer may serve to block moisture or oxygen. For example, the buffer layer may include a single inorganic layer or a plurality of stacked inorganic layers. The buffer layer may be omitted.

The thin film transistor TR may be disposed on a first buffer layer.

The thin film transistor TR includes a semiconductor layer 221, a gate electrode 222, a drain electrode 223, and a source electrode 224 disposed on the base substrate 210. A gate insulating film 225 is disposed between the semiconductor layer 221 and the gate electrode 222.

FIG. 3 illustrates the thin film transistor TR which has a top gate structure in which the gate electrode 222 is disposed on the semiconductor layer 221, but the thin film transistor TR in example embodiments of the present disclosure is not limited to this structure. In some example embodiments of the present disclosure, the thin film transistor TR may have a bottom gate structure in which the gate electrode 222 is disposed under the semiconductor layer 221. In some example embodiments of the present disclosure, the thin film transistor TR may have a double gate structure in which the gate electrode 222 is disposed on both upper and lower portions of the semiconductor layer 221.

The semiconductor layer 221 may include a silicon-based semiconductor material, an oxide-based semiconductor material, or an organic-based semiconductor material, and may have a single-layered structure or a multi-layered structure. A light shielding layer (not shown) for preventing or reducing external light incident on the semiconductor layer 221 may be additionally disposed on the base substrate 210.

The gate insulating film 225 insulates the semiconductor layer 221 from the gate electrode 222. The gate insulating film 225 may be disposed on the entire surface of the base substrate 210 to cover the semiconductor layer 221 or may be disposed only in a region where the semiconductor layer 221 and the gate electrode 222 overlap.

In some example embodiments of the present disclosure, the gate insulating film 225 may include at least one of a silicon oxide film SiOₓ and a silicon nitride film SiNₓ. In some example embodiments of the present disclosure, the gate insulating film 225 may have a multi-layered structure including the same.

The gate electrode 222 is disposed on the gate insulating film 225 while being overlapped with at least a portion of the semiconductor layer 221. The gate electrode 222 may be formed together with the gate line GL. According to an example embodiment of the present disclosure, the gate electrode 222 may include at least one of molybdenum Mo, aluminum Al, chromium Cr, gold Au, titanium Ti, nickel Ni, neodymium Nd, and copper Cu. The gate electrode 222 may have a single-layered structure or a multi-layered structure.

An interlayer insulating film 226 may be disposed on the gate electrode 222. The interlayer insulating film 226 may be formed on or disposed on the entire surface of the base substrate 210 to cover the gate electrode 222 and the gate insulating film 225.

The source electrode 224 and the drain electrode 223 may be disposed on the interlayer insulating film 226. For example, the source electrode 224 and the drain electrode 223 may be formed together with the data line DL or driving power line PL.

Each of the source electrode 224 and the drain electrode 223 may be connected to the semiconductor layer 221 through an electrode contact hole penetrating the interlayer insulating film 226 and the gate insulating film 225. The source electrode 224 and the drain electrode 223 may include at least one of molybdenum Mo, aluminum Al, chromium Cr, gold Au, titanium Ti, nickel Ni, neodymium Nd, and copper Cu.

As illustrated in FIG. 3, the planarization layer 228 is disposed on the thin film transistor TR.

The planarization layer 228 may be disposed on the entire surface of the base substrate 210 to cover the thin film transistor TR. The planarization layer 228 provides a flat surface on the thin film transistor TR. For example, the planarization layer 228 may include at least one of acryl resin, epoxy resin, phenolic resin, polyamide resin, and polyimide resin.

The planarization layer 228 may include a pixel contact hole for exposing the source electrode 224 or the drain electrode 223 of the thin film transistor TR to the first electrode 231.

The first electrode 231 of the display device 230 is disposed on the planarization layer 228. As illustrated in FIG. 3, the first electrode 231 is connected to the source electrode 224 of the thin film transistor TR through the pixel contact hole formed in or disposed in the planarization layer 228. Accordingly, the display device 230 may be connected to the thin film transistor TR, but the connection between the display device 230 and the thin film transistor TR is not limited thereto. In some example embodiments of the present disclosure, the first electrode 231 may be connected to the drain electrode 223.

The first electrode 231 of the display device 230 may be referred to as a pixel electrode or an anode.

According to an example embodiment of the present disclosure, the first electrode 231 may include a conductive material having desirable light transmittance. For example, the first electrode 231 may include a transparent conductive oxide TCO. In some example embodiments of the application, the first electrode 231 may include InSnO (ITO), but is not limited thereto. According to a light extraction structure of the display apparatus 100, the first electrode 231 may include a material having high reflectance.

A bank layer 240 is disposed on the edge of the first electrode 231. The bank layer 240 defines an emission area of the display device 230. The bank layer 240 is disposed on the planarization layer 228, to thereby define an opening area or emission area of the pixel P. The edge portion of the first electrode 231 except for the opening area may be covered by the bank layer 240. The bank layer 240 may be referred to as a pixel definition layer.

An emission layer 232 is disposed on the first electrode 231. The emission layer 232 may include an organic material. Therefore, the emission layer 232 is also referred to as an organic light emitting layer.

As illustrated in FIG. 3, the emission layer 232 is disposed on only the upper portion of the opening area of the first electrode 231 and the lateral surface of the bank layer 240, but the position of the emission layer 232 is not limited thereto. In some example embodiments of the present disclosure, the emission layer 232 may be disposed on the entire base substrate 210 to cover the first electrode 231 and the bank layer 240.

According to an example embodiment of the present disclosure, the emission layer 232 may include any one of a blue light emitting portion, a green light emitting portion, and a red light emitting portion for emitting color light corresponding to a color set in the pixel P.

In some example embodiments of the application, the emission layer 232 may emit white light. In an example embodiment of the present disclosure, the emission layer 232 may include two or more light emitting portions vertically stacked to emit white light. According to an example embodiment of the present disclosure, the emission layer 232 may include a first light emitting portion for emitting first light and a second light emitting portion for emitting second light. In this case, white light may be emitted by mixing the first light and the second light. The first light emitting portion may include any one of a blue light emitting portion, a green light emitting portion, a red light emitting portion, a yellow light emitting portion, and a yellow green light emitting portion. The second light emitting portion may include another light emitting portion for emitting the second light which is complementary to the color of the first light among the blue light emitting portion, the green light emitting portion, the red light emitting portion, the yellow light emitting portion, and the yellow green light emitting portion. When the emission layer 232 emits white light, the display apparatus 100 may further include a color filter layer (not shown). The color filter layer may be arranged in a direction in which light is emitted from the display device 230.

A second electrode 233 is disposed on the emission layer 232. The second electrode 233 may be referred to as a common electrode or a cathode.

The second electrode 233 may be in contact with the emission layer 232. The second electrode 233 may be disposed on the entire base substrate 210 so as to be commonly connected to each emission layer 232 prepared in each pixel P.

According to an example embodiment of the present disclosure, the second electrode 233 may include a metal material. In some example embodiments of the present disclosure, the second electrode 233 may include metal having high reflectance. For example, the second electrode 233 may include at least one selected from aluminum Al, titanium Ti, molybdenum Mo, magnesium Mg, silver Ag, gold Au, calcium Ca, and barium Ba. The second electrode 233 may have a single-layered structure or a multi-layered structure. The display apparatus 100 according to an example embodiment of the present disclosure has a rear emission structure in which light is emitted toward the base substrate 210.

However, example embodiments of the present disclosure are not limited thereto. In some example embodiments of the present disclosure, the second electrode 233 may include a transparent conductive material or a semi-transmissive conductive material capable of transmitting light therethrough. For example, the semi-transmissive conductive material may include magnesium Mg, silver Ag, or an alloy of magnesium Mg and silver Ag.

The display device 230 may be completed by the first electrode 231, the emission layer 232, and the second electrode 233. The display device 230 illustrated in FIG. 3 is an organic light emitting device OLED. Therefore, the display apparatus 100 according to an example embodiment of the present disclosure may be referred to as an organic light emitting display apparatus.

As illustrated in FIG. 3, a capping layer 250 may be disposed on the second electrode 233. The capping layer 250 may improve light emission efficiency by adjusting a refractive index of light emitted from the display device 230.

According to an example embodiment of the present disclosure, a stack structure from the base substrate 210 to the capping layer 250 may be referred to as the display panel 310, but is not limited thereto. In some example embodiments of the present disclosure, a stacked structure from the base substrate 210 to the display device 230 may be referred to as the display panel 310.

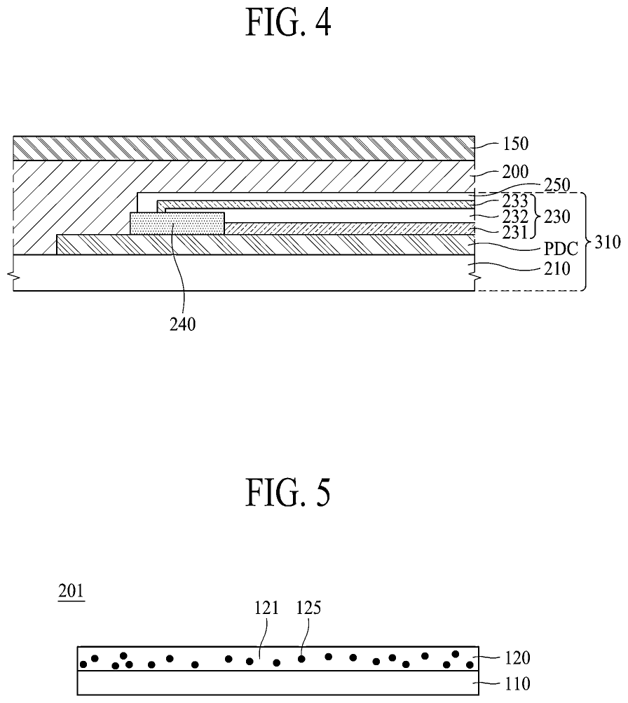

FIG. 4 is a partial cross-sectional view of the display apparatus 100 according to an example embodiment of the present disclosure.

According to an example embodiment of the present disclosure illustrated in FIG. 4, the display apparatus 100 includes the display panel 310 and an encapsulation film 200 on the display panel 310. As illustrated in FIG. 4, the display apparatus 100 may further include an encapsulation plate (encap plate) 150 on the encapsulation film 200.

According to an example embodiment of the present disclosure, the encapsulation plate 150 may include glass, metal, and the like. In some example embodiments of the present disclosure, the encapsulation plate 150 may include at least one of iron Fe, nickel Ni, aluminum Al, and titanium Ti. For example, stainless steel or Invar corresponding to an alloy of iron Fe and nickel Ni may be used as the encapsulation plate 150.

The display panel 310 may include the base substrate 210, the pixel driver PDC, the display device 230, and the capping layer 250. The base substrate 210, the pixel driver PDC, the display device 230, and the capping layer 250 have already been described, thus a detailed description thereof in relation to FIG. 4 is omitted.

In FIG. 4, the organic light emitting device OLED including the first electrode 231, the emission layer 232, and the second electrode 233 is illustrated as the display device 230.

Hereinafter, the encapsulation film 200 according to example embodiments of the present disclosure will be described in detail with reference to FIGS. 5 to 11. The encapsulation film 200 according to the example embodiments of the present disclosure will be represented by reference numerals 201, 202, and 203 in FIGS. 5, 10, and 11, respectively.

FIG. 5 is a schematic cross-sectional view of the encapsulation film 201 according to an example embodiment of the present disclosure.

The encapsulation film 201 according to an example embodiment of the present disclosure includes an adhesive layer 110 and an oxygen barrier layer 120 on the adhesive layer 110.

The adhesive layer 110 has adhesive properties. For example, the adhesive layer 110 may be attached to the display panel 310 of the display apparatus 100.

The adhesive layer 110 may include adhesive polymer. For example, the adhesive polymer may include at least one of acrylic polymer, olefin-based polymer, ester-based polymer, silicon-based polymer, amide-based polymer, rubber-based polymer, and copolymer thereof.

For example, the acrylic polymer may be acrylate-based polymer, methacrylate-based polymer, aminoacry late-based polymer, acrylonitrile-based polymer, or the like. In addition, the acrylic polymer formed by polymerization of an acrylic monomer having two or more functional groups may be used as the adhesive polymer of the adhesive layer 110.

Examples of the olefin-based polymer include ethylene-based polymer, vinyl-based polymer, vinyl alcohol-based polymer, propylene-based polymer, and copolymer thereof.

Examples of the ester-based polymer include aliphatic ester-based polymer and aromatic ester-based polymer.

Examples of the silicone-based polymer include siloxane-based polymer and alkyl siloxane-based polymer.

Examples of the amide-based polymer includes aliphatic amide-based polymer, aromatic amide-based polymer, and amide-imide polymer.

Examples of the rubber-based polymer includes butadiene-based polymer and isoprene-based rubber.

However, the adhesive polymer according to an example embodiment of the present disclosure is not limited to the polymers described above. In some example embodiments of the present disclosure, another adhesive polymer generally known to those in the art may be applied as the adhesive layer 110.

The adhesive layer 110 may further include tackifier. The tackifier may improve the adhesiveness of the adhesive layer 110 so that the adhesive layer 110 may be stably attached to the display panel 310.

In some example embodiments of the present disclosure, the adhesive layer 110 may be manufactured by applying an adhesive composition comprising an olefin-based monomer, an acrylic monomer, a rubber-based monomer, and a photoinitiator to a base film or a release film, and then polymerizing and curing the adhesive composition by a light irradiation. However, the method of manufacturing the adhesive layer 110 is not limited thereto, and the adhesive layer 110 may be manufactured by another method generally known to those in the art.

The oxygen barrier layer 120 is disposed on the adhesive layer 110. The oxygen barrier layer 120 includes binder resin 121 and oxygen collecting particles 125 dispersed in the binder resin 121.

According to an example embodiment of the present disclosure, after the oxygen barrier layer 120 and the adhesive layer 110 are separately manufactured from each other, the oxygen barrier layer 120 and the adhesive layer 110 may be attached to each other, to thereby form the encapsulation film 201. In some example embodiments of the present disclosure, the adhesive layer 110 may be formed on or disposed on the oxygen barrier layer 120. In some example embodiments of the present disclosure, the oxygen barrier layer 120 may be formed on or disposed on the adhesive layer 110, but are not limited thereto. A portion of the oxygen barrier layer 120, in which the oxygen collecting particles 125 are not arranged, may serve as the adhesive layer 110.

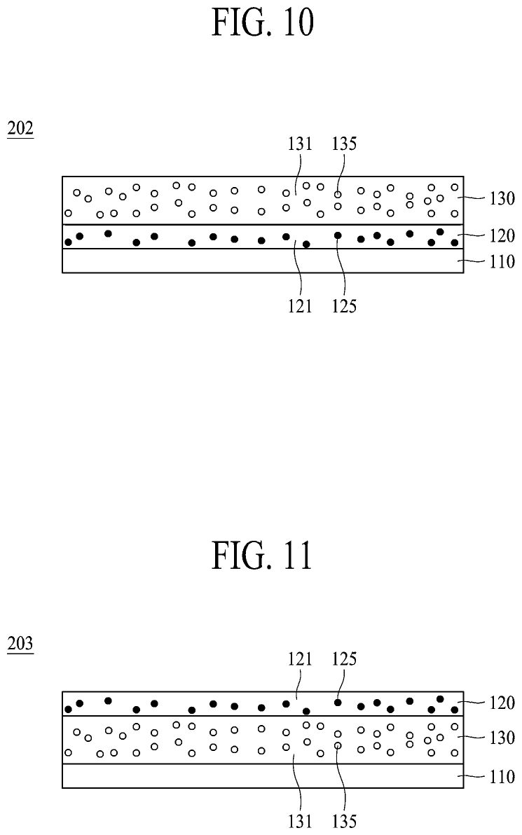

In some example embodiments of the present disclosure, one surface of the oxygen barrier layer 120 is attached to the adhesive layer 110. The other surface of the oxygen barrier layer 120 may be attached to the encapsulation plate 150 of the display apparatus 100 (see FIG. 4) and may be attached to a moisture barrier layer 130 (see FIG. 10).

The binder resin 121 may include at least one of acrylic polymer, olefin-based polymer, ester-based polymer, silicon-based polymer, amide-based polymer, rubber-based polymer, and copolymer thereof. The binder resin 121 may have adhesive properties. The binder resin 121 may include the same polymer as that of the adhesive layer 110 or may include polymer which is different from that of the adhesive layer 110.

The binder resin 121 may further include tackifier. The tackifier may improve an adhesive strength of the oxygen barrier layer 120. As a result, an adhesion between the oxygen barrier layer 120 and another layer may be improved.

In the oxygen barrier layer 120, the oxygen collecting particles 125 may exist in a state of being dispersed in the binder resin 121.

The oxygen collecting particles 125 may include a first metal oxide, and the first metal oxide may include a crystal structure including first metal sites and oxygen sites. Herein, each of the metal sites may independently be occupied by a first metal atom or a first metal cation, and each of the oxygen sites may independently be vacant, occupied by an oxygen atom or occupied by an oxygen anion (oxide). According to an example embodiment of the present disclosure, the crystal structure consisting of the first metal sites and the oxygen sites is in an oxygen deficiency state (deficiency).

According to an example embodiment of the present disclosure, in the oxygen collecting particles 125, the first metal and oxygen form the first metal oxide, and the first metal oxide is in a reduced state. In some example embodiments of the present disclosure, the oxygen collecting particles 125 may include the first metal oxide in the reduced state.

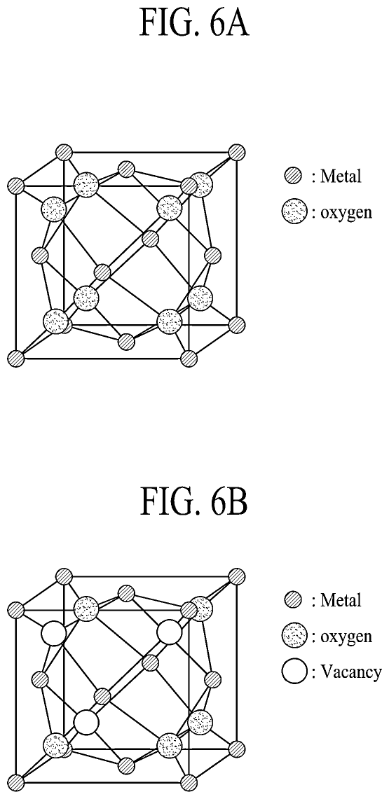

FIG. 6A is an example of a crystal structure of a first metal oxide in an oxygen saturation state, and FIG. 6B is an example of a crystal structure of a first metal oxide in an oxygen deficiency state.

FIG. 6A illustrates a face-centered-cubic FCC structure. According to an example embodiment of the present disclosure, a state in which both the first metal and oxygen are arranged at each position (site) constituting a crystal structure in a first metal oxide is referred to as a saturation state.

FIG. 6B illustrates a state in which oxygen O is missing or not disposed at a position where oxygen O is to be disposed in a crystal structure of a first metal oxide, so that a vacant oxygen site is generated. According to an example embodiment of the present disclosure, a state in which vacancy is generated at at least one of the oxygen sites in the crystal structure of the first metal oxide is referred to as an oxygen deficiency state.

According to an example embodiment of the present disclosure, the first metal oxide included in the oxygen collecting particles 125 is in a stoichiometrically oxygen deficiency state. According to an example embodiment of the present disclosure, in the first metal oxide formed by the first metal and oxygen, a state in which the number of oxygen is reduced as compared to that in the stoichiometrically saturation state is referred to as the oxygen deficiency state.

According to an example embodiment of the present disclosure, the state in which at least one vacant oxygen site is generated in the first metal oxide is referred to as the reduced state. In some example embodiments of the present disclosure, in the first metal oxide formed by the first metal and oxygen, the state in which the number of oxygen is reduced as compared to that in the stoichiometrically saturation state is referred to as the reduced state.

According to an example embodiment of the present disclosure, since the first metal oxide included in the oxygen collecting particles 125 has at least one vacant oxygen site, the first metal oxide may capture oxygen (e.g., from the atmosphere). In some example embodiments of the present disclosure, the oxygen may be captured at the vacant oxygen site that lacks oxygen. As a result, the oxygen collecting particles 125 according to an example embodiment of the present disclosure having the crystal structure in the oxygen deficiency state may easily capture or collect the oxygen.

The material in the reduced state may have the property that it is oxidized by reducing the other material. In some example embodiments of the present disclosure, the first metal oxide in the reduced state has the properties that it is oxidized itself and it reduces other materials. As described above, since the first metal oxide in the reduced state has the property of reducing other materials, it may be expressed that it has “reducing property”, whereby it may also be expressed as having the characteristics of “reducing agent”. According to an example embodiment of the present disclosure, the first metal oxide in the reduced state may be referred to as the reducing material.

Since the oxygen collecting particles 125 according to an example embodiment of the present disclosure include the first metal oxide in the reduced state, oxygen may be easily captured or collected. Therefore, the oxygen collecting particles 125 according to an example embodiment of the present disclosure may have reducibility.

The oxygen barrier layer 120 according to an example embodiment of the present disclosure including the oxygen collecting particles 125 may capture or collect the oxygen. The oxygen barrier layer 120 according to an example embodiment of the present disclosure may block the oxygen by capturing or collecting the oxygen penetrating into the oxygen barrier layer 120 through the lateral side or the surface of the oxygen barrier layer 120.

According to an example embodiment of the present disclosure, the first metal oxide having the crystal structure in the oxygen deficiency state may be manufactured by reducing the first metal oxide in a saturation state or natural state. In some example embodiments of the present disclosure, the first metal oxide in the reduced state having the oxygen deficiency may be manufactured by applying a heat treatment of a high temperature to the first metal oxide in the nitrogen environment without oxygen (nitrogen of 95 vol % or more, and hydrogen of 5 vol % or less).

The bond between the first metal and the oxygen has a bond energy. When the bond energy of the metal-oxygen bond is low, the first metal oxide may be easily reduced. However, when the first metal oxide is completely reduced and is close to pure metal, an oxygen capture or collection effect may be lowered. In addition, when the bond energy of the metal-oxygen bond is low, a reduction reaction of the first metal oxide proceeds rapidly. Thus, the oxidation number of the first metal oxide is not easily adjusted, and stability is reduced, whereby it might be difficult to use the first metal oxide as the oxygen collecting particle 125.

On the other hand, when the bond energy of the metal-oxygen bond is too high, it is not easy to reduce the first metal oxide in the natural state. For example, if the first metal oxide is conceivably reduced at a high temperature of 1500° C. or higher, agglomeration is generated due to high-temperature sintering of the first metal oxide. Thus, it may require a separate post-dispersion process, whereby the reduced first metal oxide may react again with the oxygen in the post-dispersion process, that is, it may have a problem of the oxidation of first metal oxide.

According to an example embodiment of the present disclosure, in the first metal oxide included in the oxygen collecting particle 125, the bond energy of metal-oxygen bond is greater than the bond energy of an oxygen-oxygen bond (O═O) in the oxygen molecule. In some example embodiments of the present disclosure, the first metal in which the bond energy of the first metal-oxygen bond is greater than the bond energy between the oxygen-oxygen bond (O═O) may be used as the metal of the oxygen collecting particle 125.

The bond energy of the oxygen-oxygen bond in the oxygen molecule is known to be 498 kJ. According to an example embodiment of the present disclosure, a metal, which will form a metal-oxygen bond having a bond energy greater than 498 KJ, is included in the first metal oxide of the oxygen collecting particle 125.

According to an example embodiment of the present disclosure, the first metal applied to the oxygen collecting particles 125 may be selected from metals in which the metal-oxygen bond has a bond energy greater than 498 kJ. In some example embodiments of the present disclosure, the first metal applied to the first metal oxide of the oxygen collecting particles 125 may be selected from the metals that will form a metal-oxygen bond having a bond energy greater than 498 kJ.

When the bond energy of the first metal and the oxygen included in the first metal oxide of the oxygen collecting particles 125 is greater than 498 KJ, the first metal may form a first metal-oxygen bond that is more stable than the oxygen (O)-oxygen (O) bond in the oxygen molecule O₂.

In some example embodiments of the present disclosure, when the metal-oxygen bond energy is greater than the bond energy of the oxygen (O)-oxygen (O) bond of the oxygen molecule O₂, the oxygen in the first metal oxide is more stable in terms of energy aspect than the oxygen atom in the state of oxygen molecules O₂. Thus, the oxygen may be bonded with the first metal rather than with the other oxygen atom. According to this principle, the oxygen (e.g., from the atmosphere) permeated into the oxygen barrier layer 120 may tend to occupy the oxygen deficiency position of the first metal oxide included in the oxygen collecting particles 125. The oxygen permeated from the outside may be effectively bonded to and captured by the oxygen collecting particles 125.

According to an example embodiment of the present disclosure, the bond energy of the first metal-oxygen bond included in the first metal oxide of the oxygen collecting particle 125 may be in the range of 550 kJ to 850 kJ. For example, the bond energy of the metal, which is included in the first metal oxide of the oxygen collecting particle 125, with the oxygen may be in the range of 550 kJ to 850 kJ.

When the bond energy of the first metal-oxygen bond is greater than or equal to 550 kJ, the metal-oxygen bond is more stable in terms of energy as compared to the oxygen (O)-oxygen (O) bond in the oxygen molecule O₂. Thus, the oxygen permeated into the oxygen barrier layer 120 tends to bond with the metal. As a result, oxygen-collecting ability and efficiency of the oxygen collecting particles 125 may be improved, and the oxygen barrier layer 120 may have desirable oxygen blocking ability.

When the bond energy of the first metal-oxygen bond exceeds 850 kJ, a reaction between the first metal and the oxygen is rapidly increased more than necessary such that an unnecessary side reaction, such as heating, may occur. Due to the rapid reaction between the first metal and oxygen, an unnecessary reaction may occur in the binder resin 121 or the binder resin may have a problem with curing.

Therefore, according to an example embodiment of the present disclosure, the first metal that will form a first metal-oxygen bond having a bond energy in the range of 550 KJ to 850 kJ may be used for the oxygen collecting particles 125.

According to an example embodiment of the present disclosure, the first metal oxide included in the oxygen collecting particles 125 may include one or more metals selected from actinium Ac, boron B, barium Ba, berkelium Bk, cerium Ce, curium Cm, dysprosium Dy, erbium Er, gadolinium Gd, germanium Ge, hafnium Hf, holmium Ho, lanthanum La, lawrencium Lr, ruthenium Ru, niobium Nb, neodymium Nd, neptunium Np, zirconium Zr, and osmium Os.

For example, the first metal oxide included in the oxygen collecting particles 125 may include cerium Ce as the first metal.

According to example embodiments of the present disclosure, the oxygen collecting particles 125 may include cerium oxide represented by the following chemical formula 1,

CeOₓ [Chemical Formula 1]
herein, it satisfies that 1.5<x<2.

In the oxygen collecting particle 125, the cerium oxide CeOₓ is in the oxygen deficiency state as compared to CeO₂ corresponding to a stable cerium tetravalent (IV) oxide. Thus, the cerium oxide represented by the above chemical formula 1 may be referred to as the reduced state. The cerium oxide CeOₓ represented by the above chemical formula 1 is in the reduced state and has relatively strong reducibility. Therefore, the cerium oxide CeOₓ represented by the above chemical formula 1 may have desirable oxygen collecting characteristics.

According to example embodiments of the present disclosure, the cerium oxide CeOₓ represented by the chemical formula 1 has a crystal structure formed by or consists of cerium Ce at the first metal sites, oxygen O at the oxygen sites, and at least one oxygen site being vacant. Since the oxygen may be easily captured or collected in vacant oxygen site(s) in the crystal structure of the cerium oxide, the cerium oxide represented by the chemical formula 1 has desirable oxygen collecting ability. As a result, the oxygen collecting particle 125 including the cerium oxide represented by the chemical formula 1 may have desirable oxygen collecting ability.

According to example embodiments of the present disclosure, in the nitrogen environment without oxygen (nitrogen gas of 95 vol % or more and hydrogen gas of 5 vol % or less). CeO₂ corresponding to the cerium tetravalent (IV) oxide is heat-treated at a high temperature of about 1100° C. for 12 hours so that it is possible to manufacture CeOₓ (1.5<x<2) corresponding to the cerium oxide of the reduced state having the oxygen deficiency. The cerium oxide in the reduced state may represent a deep blue or dark blue.

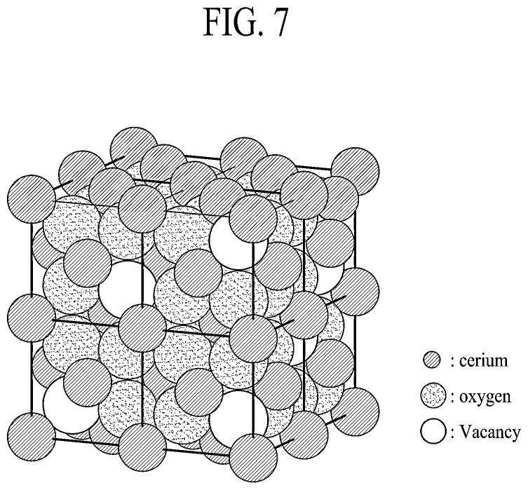

FIG. 7 is a schematic diagram of a crystal structure of cerium oxide CeOₓ according to an example embodiment of the present disclosure.

As illustrated in FIG. 7, the crystal of cerium oxide according to an example embodiment of the present disclosure may have a cubic structure and may be deficient in oxygen at a vacant oxygen site. In some example embodiments of the present disclosure, the cerium oxide according to an example embodiment of the present disclosure may have a basic crystal structure in which oxygen O is disposed in a face-centered-cubic FCC structure formed by cerium Ce and may have a structure in which an oxygen is missing in the basic crystal structure. As illustrated in FIG. 7, in the crystal structure of cerium oxide, at least one of the oxygen sites is vacant. In FIG. 7, a vacancy indicates a vacant oxygen site.

The inventors of the present disclosure have found that CeOₓ (1.5<x<2) corresponding to the cerium oxide formed when CeO₂ corresponding to the cerium tetravalent (IV) oxide having the cubic structure is partially reduced has desirable oxygen collecting and blocking properties, and then completed the present disclosure.

The cerium oxide may include Ce₂O₃ having a hexagonal structure. The oxygen collecting and blocking efficiency in the cerium oxide Ce₂O₃ having the hexagonal structure and the oxide formed by partially reducing Ce₂O₃ may be lower than CeOₓ (1.5<x<2) and the stability of oxygen collection in the cerium oxide Ce₂O₃ having the hexagonal structure and the oxide formed by partially reducing Ce₂O₃ may be relatively lower as compared to that of CeOₓ (1.5<x<2).

In an example embodiment of the present disclosure, the oxide represented by CeOₓ (1.5<x<2) in the cerium oxide is used for the oxygen collecting particle 125.

In the cerium oxide CeOₓ, if ‘x’ is 1.5 or less, the cerium oxide has a crystal structure of Ce₂O₃ having the hexagonal structure, and may degrade the oxygen collecting and blocking efficiency by the cerium oxide. If ‘x’=2, the oxygen collecting efficiency of cerium oxide may be low since the oxygen may be in the saturated state in the cerium oxide. Also, it may not be easy to manufacture a compound having ‘x’ larger than 2 (as in CeOₓ). Therefore, in an example embodiment of the present disclosure, the oxide represented by CeOₓ (1.5<x<2) is used as the cerium oxide.

In some example embodiments of the present disclosure, in CeOₓ as the cerium oxide applied to the oxygen collecting particle 125, ‘x’ may be in the range of 1.51 to 1.99 and may be in the range of 1.55 to 1.95. Alternatively, in CeOₓ as the cerium oxide applied to the oxygen collecting particle 125, ‘x’ may be in the range of 1.6 to 1.9, ‘x’ may be in the range of 1.65 to 1.9, and ‘x’ may be in the range of 1.65 to 1.85, for the more stable manufacturing of the cerium oxide and the more stable oxygen collection,

For example, the crystal structure of cerium oxide CeOₓ may be identified by X-ray diffraction analysis.

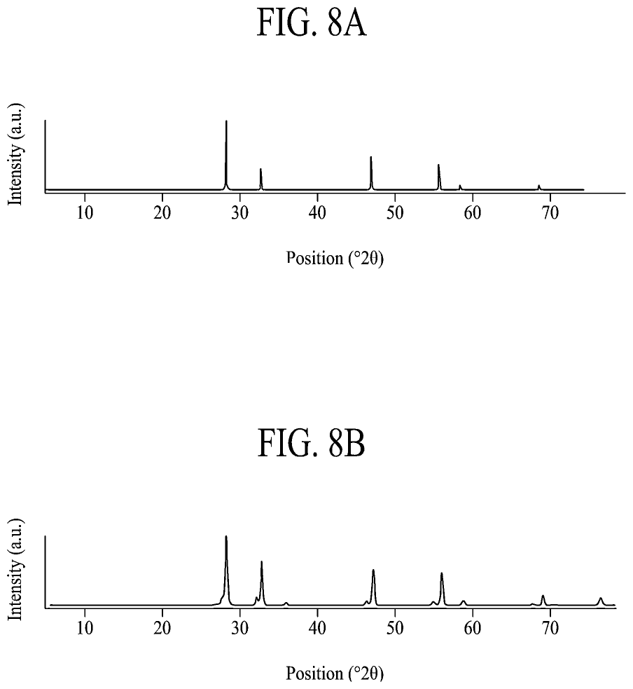

FIGS. 8A and 8B are X-ray diffraction analysis graphs of cerium oxide.

FIG. 8A is an X-ray diffraction analysis graph for the oxide CeO₂ in the oxygen saturation state, and FIG. 8B is an X-ray diffraction analysis graph for the oxide CeO_{1.7} (x=1.7).

According to example embodiments of the present disclosure, the oxidation number of cerium oxide CeOₓ may be adjusted by adjusting the condition for reducing CeO₂ corresponding to the cerium tetravalent (IV) oxide, and the oxidation number (or ‘x’ value) of the cerium oxide CeOₓ may be confirmed by using the X-ray diffraction analysis graph.

According to an example embodiment of the present disclosure, the oxygen barrier layer 120 may include the oxygen collecting particles 125 at a content of 0.5 to 50 wt % based on the total weight of the oxygen barrier layer 120.

When the content of the oxygen collecting particles 125 is less than 0.5 wt % with respect to the total weight of the oxygen barrier layer 120, the amount of oxygen collecting particles 125 may not be sufficient. The oxygen collecting and blocking functions of the oxygen barrier layer 120 may not be sufficiently realized.

On the other hand, when the content of the oxygen collecting particles 125 exceeds 50 wt % with respect to the total weight of the oxygen barrier layer 120, dispersibility of the oxygen collecting particles 125 may be lowered due to the excessive amount of oxygen collecting particles 125. An agglomeration phenomenon of the oxygen collecting particles 125 may occur during the manufacturing process of the oxygen barrier layer 120, and the adhesion, flexibility, and workability of the oxygen barrier layer 120 may be degraded.

In some example embodiments of the present disclosure, the oxygen barrier layer 120 may include the oxygen collecting particles 125 at 1 to 30 wt % based on the total weight of the oxygen barrier layer 120 in consideration of the oxygen collecting and blocking functions, the adhesion, the flexibility, and the workability. In some example embodiments of the present disclosure, the oxygen barrier layer 120 may include the oxygen collecting particles 125 at 5 to 30 wt %.

According to an example embodiment of the present disclosure, the oxygen barrier layer 120 may have a thickness of 5 to 50 μm. When the thickness of the oxygen barrier layer 120 is less than 5 μm, the oxygen collecting and blocking functions of the oxygen barrier layer 120 may not be sufficiently realized due to the small thickness. On the other hand, when the thickness of the oxygen barrier layer 120 exceeds 50 μm, the thickness of the encapsulation film 201 may be thicker than necessary. In addition, since the oxygen collecting and blocking functions of the oxygen barrier layer 120 may not be proportionally increased by increasing the thickness of the oxygen barrier layer 120, the oxygen barrier layer 120 may not have a large thickness exceeding 50 μm.

In some example embodiments of the present disclosure, the oxygen barrier layer 120 may have a thickness of 5 to 20 μm in consideration of balance of the oxygen collecting and blocking functions, workability, and economic feasibility.

According to an example embodiment of the present disclosure, the oxygen collecting particles 125 may have an average particle diameter of 0.5 to 10 μm. According to an example embodiment of the present disclosure, the average particle diameter may be referred to as a particle size. In addition, the average particle diameter of the oxygen collecting particles 125 may be defined as an average value of the maximum diameter of each oxygen collecting particle 125.

When the average particle diameter of the oxygen collecting particles 125 is less than 0.5 μm, it might be difficult to disperse the oxygen collecting particles 125 during the manufacturing process of the oxygen barrier layer 120, and it might be difficult to realize the stable crystal structure of the metal oxide. The oxygen collecting and blocking efficiency may be degraded.

On the other hand, when the average particle diameter of the oxygen collecting particles 125 exceeds 10 μm, the surface of the oxygen barrier layer 120 may not be flat due to the large particle size. The adhesion efficiency may be deteriorated. In addition, since the number of oxygen collecting particles 125 that may be included in the oxygen barrier layer 120 is limited, it might cause limits in the oxygen collecting amount of the oxygen barrier layer 120.

In some example embodiments of the present disclosure, the oxygen collecting particles 125 may have the average particle diameter of 1 to 5 μm in consideration of the ease in the manufacture process of the oxygen barrier layer 120, the oxygen collecting efficiency, and the adhesiveness. In some example embodiments of the present disclosure, the oxygen collecting particles 125 may have the average particle diameter of 1 to 3 μm.

According to an example embodiment of the present disclosure, the encapsulation film 201 may represent a blue color. In some example embodiments of the present disclosure, the oxygen barrier layer 120 of the encapsulation film 201 may represent a blue color.

According to an example embodiment of the present disclosure, the color may be represented by CIE color coordinates.

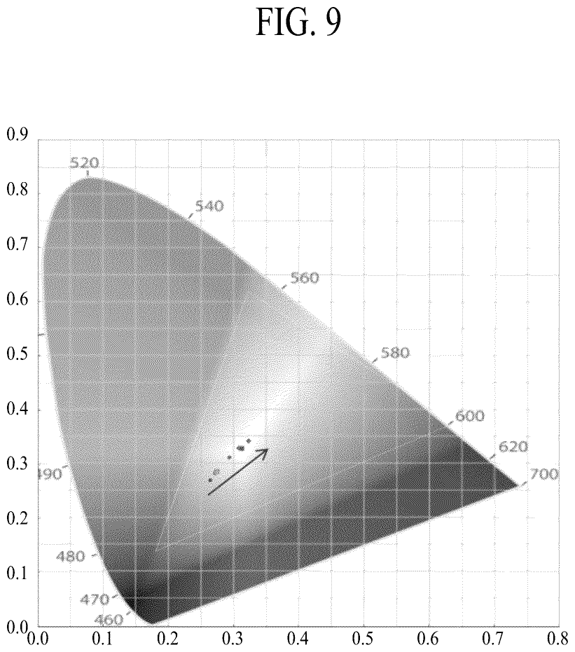

FIG. 9 is the CIE 1931 color coordinates in which the horizontal axis corresponds to the ‘x’ values and the vertical axis corresponds to the ‘y’ values. According to an example embodiment of the present disclosure, the color may be displayed by using CIE 1931 xy color coordinates.

For example, based on CIE 1931 xy color coordinates, the oxygen barrier layer 120 may have the blue color having an ‘x’ value in the range of 0.25 to 0.29 and a ‘y’ value in the range of 0.25 to 0.29.

According to an example embodiment of the present disclosure, when CeOₓ (1.5<x<2) of the cerium oxide is used as the oxygen collecting particle 125, the oxygen barrier layer 120 may have the blue color having an ‘x’ value in the range of 0.25 to 0.29 and a ‘y’ value in the range of 0.25 to 0.29. In some example embodiments of the present disclosure, based on CIE 1931 xy color coordinates, the oxygen barrier layer 120 may have the blue color having an ‘x’ value in the range of 0.27 to 0.29 and a ‘y’ value in the range of 0.27 to 0.29.

When the oxygen barrier layer 120 has a blue color, the encapsulation film 201 may also appear blue.

When the oxygen barrier layer 120 is in contact with oxygen molecule, the color of the oxygen barrier layer 120 may change. In some example embodiments of the present disclosure, when the oxygen permeates into the oxygen barrier layer 120, the oxygen collecting particles 125 may be oxidized by capturing or collecting the oxygen. The color of the oxygen collecting particles 125 may change, leading to a change in the color of the oxygen barrier layer 120.

According to an example embodiment of the present disclosure, the oxygen barrier layer 120 is in contact with oxygen molecule, and the color of oxygen barrier layer 120 may change into a white color having an ‘x’ value in the range of 0.31 to 0.35 and a ‘y’ value in the range of 0.32 to 0.36, based on CIE 1931 xy color coordinates. In some example embodiments of the present disclosure, the oxygen barrier layer 120 is in contact with oxygen molecule, and the color of oxygen barrier layer 120 may be changed into the white color having an ‘x’ value in the range of 0.32 to 0.34 and a ‘y’ value in the range of 0.33 to 0.35, based on CIE 1931 Xy color coordinates. In some example embodiments of the present disclosure, the oxygen barrier layer 120 is in contact with oxygen molecule, and the color of oxygen barrier layer 120 may be changed into the white color having an ‘x’ value close to 0.33 and a ‘y’ value close to 0.34, based on CIE 1931 xy color coordinates.

In FIG. 9, a color path in which the color of the oxygen barrier layer 120 changes by contact with oxygen molecule is indicated by an arrow:

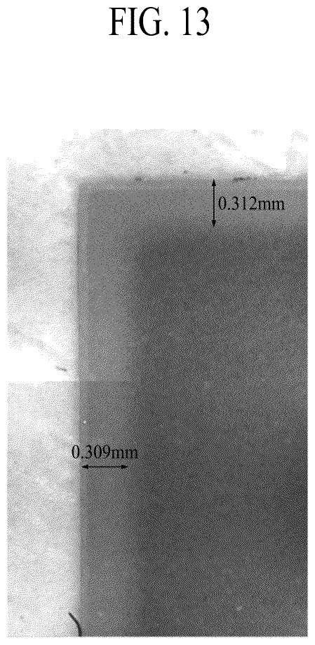

According to an example embodiment of the present disclosure, only the part of the oxygen barrier layer 120 in contact with oxygen molecule has its color changed into white color (see, for example, FIG. 13).

FIG. 10 is a schematic cross-sectional view of an encapsulation film 202 according to another example embodiment of the present disclosure. To avoid redundancy, hereinafter, descriptions of components already described will be omitted.

The encapsulation film 202 according to another example embodiment of the present disclosure may include a moisture barrier layer 130 disposed on an oxygen barrier layer 120. As illustrated in FIG. 10, the encapsulation film 202 may include an adhesive layer 110, the oxygen barrier layer 120 on the adhesive layer 110, and the moisture barrier layer 130 on the oxygen barrier layer 120.

FIG. 10 illustrates the encapsulation film 202 in which the oxygen barrier layer 120 is disposed between the adhesive layer 110 and the moisture barrier layer 130, but is not limited thereto. In some example embodiments of the present disclosure, the moisture barrier layer 130 may be disposed between the adhesive layer 110 and the oxygen barrier layer 120.

The moisture barrier layer 130 may include adhesive resin 131 and moisture absorbent 135 dispersed in the adhesive resin 131.

The adhesive resin 131 may include at least one selected from acrylic polymer, olefin-based polymer, ester-based polymer, silicon-based polymer, amide-based polymer, rubber-based polymer, and copolymer thereof.

The adhesive resin 131 of the moisture barrier layer 130 may include the same polymer as that of the adhesive layer 110 or may include other polymers.

In some example embodiments of the present disclosure, one surface of the moisture barrier layer 130 may be attached to the oxygen barrier layer 120, and the other surface of the moisture barrier layer 130 may be attached to an encapsulation plate 150 of a display apparatus 100 (see, for example, FIG. 4).

The moisture barrier layer 130 may further include tackifier. The tackifiers may improve the adhesion of the moisture barrier layer 130.

The moisture absorbent 135 may absorb or adsorb moisture.

The moisture absorbent 135 includes a second metal oxide, and the second metal oxide includes a second metal and oxygen. According to another example embodiment of the present disclosure, in the second metal oxide included in the moisture absorbent 135, a bond energy of the metal-oxygen bond is smaller than a bond energy between the two oxygens (O—O) in an oxygen molecule.

For example, the bond energy of the metal-oxygen bond in the second metal oxide included in the moisture absorbent 135 may be less than 498 kJ.

According to another example embodiment of the present disclosure, the moisture absorbent 135 may include calcium oxide CaO, but not limited thereto. The calcium oxide CaO has desirable moisture absorption characteristics. Another moisture absorbent generally known to those in the art may be used for the moisture absorbent 135 of the encapsulation film 202 according to another example embodiment of the present disclosure.

The moisture absorbent 135 may have a particle shape and may have an average particle diameter of 1 to 10 μm. The average particle diameter of the moisture absorbent 135 may be defined as an average value of the maximum diameter of each moisture absorbent 135.

When the average particle diameter of the moisture absorbent 135 is less than 1 μm, it may be difficult to disperse the moisture absorbent 135 in the process of manufacturing the moisture barrier layer 130. On the other hand, when the average particle diameter of the moisture absorbent 135 exceeds 10 μm, the surface of the moisture barrier layer 130 may not be flat due to the large particle size. The adhesion efficiency may be deteriorated. In some example embodiments of the present disclosure, since the number of moisture absorbent 135 that may be included in the moisture barrier layer 130 is limited, it might degrade or decrease the moisture absorption efficiency of the moisture barrier layer 130.

The moisture barrier layer 130 may have a thickness of 20 to 1000 μm. When the thickness of the moisture barrier layer 130 is less than 20 μm, the moisture absorption and blocking function of the moisture barrier layer 130 may not be sufficiently realized. On the other hand, when the thickness of the moisture barrier layer 130 exceeds 1000 μm, the thickness of the encapsulation film may be thicker than necessary. In addition, since the moisture absorption and blocking function of the moisture barrier layer 130 may not be proportionally increased by increasing the thickness of the moisture barrier layer 130, the moisture barrier layer 130 may not have a large thickness over 1000 μm.

In some example embodiments of the present disclosure, the moisture barrier layer 130 may have a thickness of 20 to 100 μm in consideration of the balance of moisture absorption and blocking functions, workability, and economic feasibility.

FIG. 11 is a schematic cross-sectional view of an encapsulation film 203 according to another example embodiment of the present disclosure.

As illustrated in FIG. 11, the moisture barrier layer 130 may be disposed between the adhesive layer 110 and the oxygen barrier layer 120. Since the adhesive layer 110, the oxygen barrier layer 120, and the moisture barrier layer 130 have already been described, a detailed description thereof will be omitted.

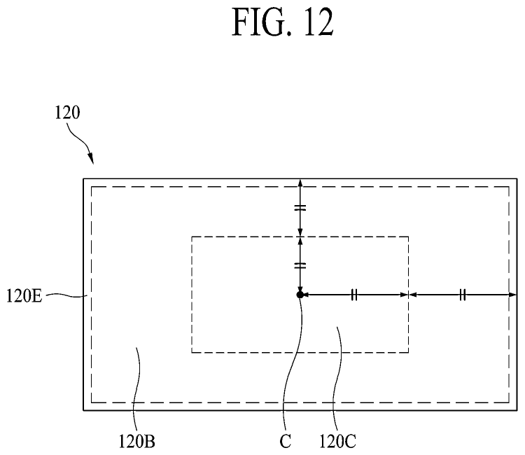

FIG. 12 is a plan view of an oxygen barrier layer 120 according to an example embodiment of the present disclosure. FIG. 12 corresponds to a plan view of the encapsulation film 200 according to an example embodiment of the present disclosure.

As illustrated in FIG. 12, the oxygen barrier layer 120 has a central portion 120C, an edge portion 120E, and a middle portion 120B. The central portion 120C, the edge portion 120E, and a middle portion 120B of the oxygen barrier layer 120 illustrated in FIG. 12 correspond to the central portion, the edge portion, and the middle portion of the encapsulation film 200, respectively.

The central portion 120C of the oxygen barrier layer 120 illustrated in FIG. 12 is positioned within 50% of a distance between a center point C and an edge end of the oxygen barrier layer 120 with respect to the center point C of the oxygen barrier layer 120. The central portion 120C of the oxygen barrier layer 120 is indicated by a dotted line in FIG. 12. The edge end of the oxygen barrier layer 120 corresponds to a solid line defining the oxygen barrier layer 120 in FIG. 12.

According to an example embodiment of the present disclosure, the edge portion 120E of the oxygen barrier layer 120 may be defined as a portion within 500 μm from the edge end of the oxygen barrier layer 120. In FIG. 12, the edge portion 120E of the oxygen barrier layer 120 is indicated by a dotted line.

The middle portion 120B of the oxygen barrier layer 120 is positioned between the central portion 120C and the edge portion 120E of the oxygen barrier layer 120.

According to an example embodiment of the present disclosure, even when the encapsulation film 200 is applied to the display apparatus 100, the central portion 120C of the oxygen barrier layer 120 is not contaminated by the oxygen, thereby preventing or reducing discoloration.

In some example embodiments of the present disclosure, the edge portion 120E of the oxygen barrier layer 120 may be contaminated by the oxygen and may be discolored. In some example embodiments of the present disclosure, the oxygen is permeated into at least a portion of the edge portion 120E of the oxygen barrier layer 120, and then the oxygen collecting particles 125 may react with the oxygen and may be discolored. As a result, at least a portion of the edge portion 120E of the oxygen barrier layer 120 may be discolored to a white-based color.

In the display apparatus 100 according to an example embodiment of the present disclosure, the central portion 120C of the oxygen barrier layer 120 may have a color having an ‘x’ value in the range of 0.25 to 0.29 and a ‘y’ value in the range of 0.25 to 0.29, based on CIE 1931 xy color coordinates. For example, when cerium oxide CeOₓ (1.5<x<2) is used for the oxygen collecting particles 125 of the oxygen barrier layer 120, the central portion 120C of the oxygen barrier layer 120 may maintain a blue color. In some example embodiments of the present disclosure, the central portion 120C of the oxygen barrier layer 120 may have a blue-based color having an ‘x’ value in the range of 0.27 to 0.29 and a ‘y’ value in the range of 0.27 to 0.29, based on CIE 1931 xy color coordinates.

In some example embodiments of the present disclosure, when cerium oxide CeOₓ (1.5<x<2) is used for the oxygen collecting particles 125 of the oxygen barrier layer 120, the cerium oxide CeOₓ reacts with the oxygen in at least a portion of the edge portion 120E of the oxygen barrier layer 120. At least a portion of the edge portion 120E of the oxygen barrier layer 120 may be discolored to a white-based color.

FIG. 13 is a photograph showing a portion of the oxygen barrier layer 120. In some example embodiments of the present disclosure, FIG. 13 is a photograph showing the oxygen barrier layer 120 of the encapsulation film 202 after exposing the display apparatus 100, to which the encapsulation film 202 according to an example embodiment of the present disclosure is attached, to a room temperature and a normal pressure environment for 200 hours.

As illustrated in FIG. 13, it may be confirmed that a portion positioned within 0.312 mm (upper portion. 312 μm) from the edge end of the oxygen barrier layer 120 and a portion positioned within 0.309 mm (left portion, 309 μm) from the edge end of the oxygen barrier layer 120 are discolored into a white-based color.

As described above, according to an example embodiment of the present disclosure, when the display apparatus 100, to which the encapsulation film 200 including the oxygen barrier layer 120 is attached, is exposed to a room temperature for a long time, for example, 200 hours or more, at least a portion of the edge portion 120E of the oxygen barrier layer 120 is discolored. Particularly, as illustrated in FIG. 13, it may be confirmed that a portion positioned within at least 300 μm from the edge end of the oxygen barrier layer 120 is discolored to a color having an ‘x’ value in the range of 0.31 to 0.35 and a ‘y’ value in the range of 0.32 to 0.36, based on CIE 1931 xy color coordinates.

As the time for which the display apparatus 100 or the encapsulation film 200 is exposed to the oxygen or air increases, a penetration distance of oxygen into the inside of the encapsulation film 200 will be further increased. For example, when the display apparatus 100 or the encapsulation film 200 is exposed to the air for 6 weeks (1008 hours) or more, a portion positioned within at least 500 μm from the edge end of the oxygen barrier layer 120 may be discolored to a white color. In this case, a portion positioned within at least 500 μm from the edge end of the oxygen barrier layer 120 may be discolored to a color having an ‘x’ value in the range of 0.31 to 0.35 and ‘y’ value in the range of 0.32 to 0.36, based on CIE 1931 xy color coordinates.

As described above, when the encapsulation film 200 according to an example embodiment of the present disclosure is used for the display apparatus, the edge portion of the encapsulation film 200 is discolored. Through this discoloration, it is possible to determine a contamination degree caused by the oxygen in the display apparatus. Therefore, the encapsulation film 200 and the oxygen barrier layer 120 according to the present disclosure may serve as an indicator for the oxygen contamination.

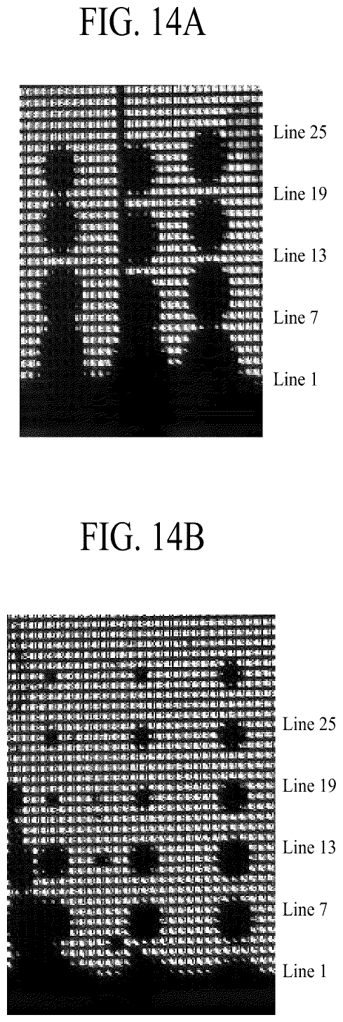

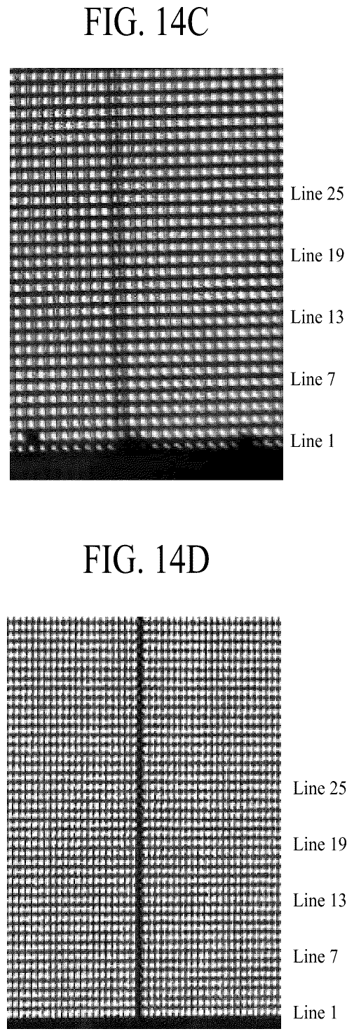

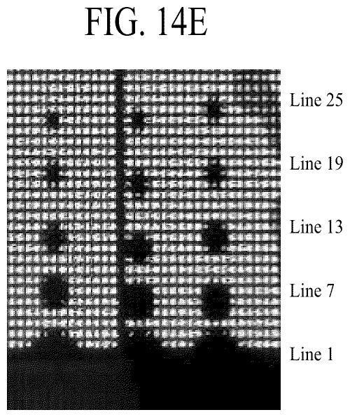

FIG. 14A is a photograph that shows the occurrence of dark spots in a display apparatus according to a reference embodiment.

FIGS. 14B and 14E are each a photograph that shows the occurrence of dark spots in a display apparatus according to a comparative embodiment.

FIGS. 14C and 14D are each a photograph that shows the occurrence of dark spots or the lack of thereof in a display apparatus according to an example embodiment of the present disclosure.

FIG. 14A shows dark spots generated in a display panel 310, which is photographed in a display apparatus according to a reference example provided with an encapsulation film 200 which does not include cerium oxide after exposure of 200 hours in a room temperature and atmospheric pressure environment. The encapsulation film 200 applied to the display apparatus corresponding to the reference embodiment in FIG. 14A includes only an adhesive layer 110 and a moisture barrier layer 130 and does not include an oxygen barrier layer 120.

FIG. 14B shows a display panel 310, which is photographed in a display apparatus provided with an encapsulation film 200 which includes cerium oxide expressed as CeO_{1.5} (x=1.5) for oxygen collecting particles 125 after exposure of 200 hours in a room temperature and atmospheric pressure environment. The encapsulation film 200 applied to the display apparatus corresponding to the comparative embodiment of FIG. 14B includes an adhesive layer 110, an oxygen barrier layer 120, and a moisture barrier layer 130.

FIG. 14C shows a display panel 310, which is photographed in a display apparatus provided with an encapsulation film 200 which include cerium oxide expressed as CeO_{1.6} (x=1.6) for oxygen collecting particles 125 after exposure of 200 hours in a room temperature and atmospheric pressure environment. The encapsulation film 200 applied to the display apparatus corresponding to the example embodiment of FIG. 14C includes an adhesive layer 110, an oxygen barrier layer 120, and a moisture barrier layer 130.

FIG. 14D shows a display panel 310, which is photographed in a display apparatus provided with an encapsulation film 200 which include cerium oxide expressed as CeO_{1.7} (x=1.7) for oxygen collecting particles 125 after exposure of 200 hours in a room temperature and atmospheric pressure environment. The encapsulation film 200 applied to the display apparatus corresponding to the example embodiment of FIG. 14D includes an adhesive layer 110, an oxygen barrier layer 120, and a moisture barrier layer 130.

FIG. 14E shows a display panel 310, which is photographed in a display apparatus provided with an encapsulation film 200 which include cerium oxide expressed as CeO_{2.0} (x=2.0) for oxygen collecting particles 125 after exposure of 200 hours in a room temperature and atmospheric pressure environment. The encapsulation film 200 applied to the display apparatus corresponding to the comparative embodiment of FIG. 14E includes an adhesive layer 110, an oxygen barrier layer 120, and a moisture barrier layer 130.

When the pixel P disposed on the display panel 310 is damaged, the pixel P does not emit light, and a dark point (dark spot) is generated in the display panel 310.

In FIG. 14A, the dark point is observed from the edge of the display panel 310 to the 25th pixel P line on the display panel 310. As illustrated in FIG. 14A, when the encapsulation film 200 that does not include the oxygen barrier layer 120 is used, the pixel P is damaged by the oxygen permeation to generate the dark point in the display panel 310.

In FIG. 14B, the dark point is observed from the edge of the display panel 310 to the 25th pixel P line on the display panel 310. However, the dark point observed in FIG. 14B is smaller than the dark spot observed in FIG. 14A. As illustrated in FIG. 14B, when the cerium oxide expressed as CeO_{1.5} (x=1.5) is used for the oxygen collecting particles 125, an oxygen blocking effect is inferior, and the pixel P is damaged by the oxygen permeation to generate the dark point in the display panel 310.

In FIG. 14C, one dark point is observed in the first pixel P line from the edge of the display panel 310. As illustrated in FIG. 14C, when the cerium oxide expressed as CeO_{1.6} (x=1.6) is used for the oxygen collecting particles 125, an oxygen blocking effect is exhibited by the oxygen barrier layer 120, and the pixel P is hardly damaged by the oxygen permeation. Dark points are hardly generated in the display panel 310.

In FIG. 14D, the dark point is not observed in the display panel 310. As illustrated in FIG. 14D, when the cerium oxide expressed as CeO_{1.7} (x=1.7) is used for the oxygen collecting particles 125, an oxygen blocking effect is exhibited by the oxygen barrier layer 120, and the pixel P is not damaged by the oxygen permeation. No dark point is generated in the display panel 310.

In FIG. 14E, the dark point is observed from the edge of the display panel 310 to the inside of the 25th pixel line on the display panel 310. However, the dark point observed in FIG. 14E is smaller than the dark spot observed in FIG. 14A. As illustrated in FIG. 14E, when the cerium oxide expressed as CeO_{2.0} (x=2.0) is used for the oxygen collecting particles 125, an oxygen blocking effect is inferior, and the pixel P is damaged by the oxygen permeation to generate the dark point in the display panel 310.

As a result, when the cerium oxide expressed as CeOₓ (1.5<x<2) is used for the oxygen collecting particles 125 of the oxygen barrier layer 120, the oxygen barrier layer 120 has desirable oxygen blocking effect. The encapsulation film 200 of the oxygen barrier layer 120 has desirable oxygen blocking effect so that it is possible to protect the pixel P from the oxygen. Accordingly, the pixel P is not damaged such that the dark spot does not occur or almost does not occur on the display screen of the display panel 310 of the display apparatus 100.

The encapsulation film according to an example embodiment of the present disclosure has the oxygen barrier layer so that it may be possible to realize desirable oxygen blocking properties. In addition, the display apparatus according to an example embodiment of the present disclosure includes the encapsulation film having desirable oxygen blocking properties, thereby effectively blocking oxygen introduced into the display apparatus from the outside.

According to an example embodiment of the present disclosure, the oxygen-collecting portion may be selectively discolored in the encapsulation film so that it may be possible to easily determine the contamination level of the encapsulation film caused by the oxygen. In addition, the display apparatus according to another example embodiment of the present disclosure includes the encapsulation film capable of determining the contamination caused by the oxygen so that it is possible to easily determine the contamination level of the display apparatus caused by the oxygen.

It will be apparent to those skilled in the art that various substitutions, modifications, and variations can be made in the present disclosure without departing from the technical idea or scope of the disclosure. Thus, it is intended that embodiments of the present disclosure cover the modifications and variations of the disclosure provided they come within the scope of the appended claims and their equivalents.

What is claimed is:

1. A display apparatus comprising:
a display panel; and
an encapsulation film on the display panel, the encapsulation film including:
an adhesive layer; and
an oxygen barrier layer on the adhesive layer, the oxygen barrier layer including:
binder resin, and
oxygen collecting particles dispersed in the binder resin, the oxygen collecting particles including a first metal oxide that includes a crystal structure consisting of first metal sites and oxygen sites, wherein the crystal structure is in an oxygen deficiency state.

2. The display apparatus according to claim 1, wherein the first metal oxide is in a reduced state.

3. The display apparatus according to claim 1, wherein a bond energy of a first metal-oxygen bond is greater than a bond energy of an oxygen-oxygen bond in an oxygen molecule O₂.

4. The display apparatus according to claim 3, wherein the bond energy of the first metal-oxygen bond is greater than 498 kJ.

5. The display apparatus according to claim 4, wherein the bond energy of the first metal-oxygen bond is in a range of 550 kJ to 850 kJ.

6. The display apparatus according to claim 1, wherein the first metal oxide includes at least one metal selected from actinium Ac, boron B, barium Ba, berkelium Bk, cerium Ce, curium Cm, dysprosium Dy, erbium Er, gadolinium Gd, germanium Ge, hafnium Hf, holmium Ho, lanthanum La, lawrencium Lr, ruthenium Ru, niobium Nb, neodymium Nd, neptunium Np, zirconium Zr, and osmium Os.

7. The display apparatus according to claim 1, wherein the first metal oxide includes a cerium oxide represented by Chemical Formula 1:
CeOₓ [Chemical Formula 1]
wherein 1.5<x<2.

8. The display apparatus according to claim 7,
wherein the first metal oxide is the cerium oxide, and
wherein the crystal structure consists of:
cerium at the first metal sites,
oxygen at the oxygen sites, and
at least one oxygen site being vacant.

9. The display apparatus according to claim 1, wherein the oxygen barrier layer includes the oxygen collecting particles at a content of 0.5 to 50 wt % based on a total weight of the oxygen barrier layer.

10. The display apparatus according to claim 1, wherein the oxygen barrier layer has a thickness of 5 to 50 μm.

11. The display apparatus according to claim 10, wherein the oxygen barrier layer has a thickness of 5 to 20 μm.

12. The display apparatus according to claim 1, wherein the oxygen collecting particles have an average particle diameter of 0.5 to 10 μm.

13. The display apparatus according to claim 12, wherein the oxygen collecting particles have an average particle diameter of 1 to 3 μm.

14. The display apparatus according to claim 1, wherein the binder resin includes at least one binder selected from an acrylic polymer, an olefin-based polymer, an ester-based polymer, a silicon-based polymer, an amide-based polymer, a rubber-based polymer, and a copolymer thereof.

15. The display apparatus according to claim 1, wherein the oxygen barrier layer has a blue color having an ‘x’ value in a range of 0.25 to 0.29 and a ‘y’ value in a range of 0.25 to 0.29, based on CIE 1931 xy color coordinates.

16. The display apparatus according to claim 15, wherein the oxygen barrier layer is configured to change from the blue color to a white color having the ‘x’ value in a range of 0.31 to 0.35 and the ‘y’ value in the range of 0.32 to 0.36, based on the CIE 1931 xy color coordinates, when the oxygen barrier layer is in contact with oxygen molecule.

17. The display apparatus according to claim 1,
wherein the encapsulation film further includes a moisture barrier layer disposed on the oxygen barrier layer, and
the moisture barrier layer includes adhesive resin and absorbent dispersed in the adhesive resin.

18. The display apparatus according to claim 17,
wherein the absorbent includes a second metal oxide,
the second metal oxide includes a second metal and oxygen, and
a bond energy of a second metal-oxygen bond in the second metal oxide is smaller than a bond energy of an oxygen-oxygen bond in an oxygen molecule.

19. The display apparatus according to claim 17, wherein the second metal oxide includes calcium oxide CaO.

20. The display apparatus according to claim 1,
wherein a central portion of the oxygen barrier layer has a color having an ‘x’ value in a range of 0.25 to 0.29 and a ‘y’ value in a range of 0.25 to 0.29, based on CIE 1931 xy color coordinates, and
a portion positioned within at least 300 μm from an edge end of the oxygen barrier layer has a color having the ‘x’ value in a range of 0.31 to 0.35 and the ‘y’ value in a range of 0.32 to 0.36, based on the CIE 1931 xy color coordinates,
wherein the central portion of the oxygen barrier layer is positioned within 50% of a distance between a center point and an edge end of the oxygen barrier layer from the center point of the oxygen barrier layer.

21. An encapsulation film comprising:
an adhesive layer; and
an oxygen barrier layer on the adhesive layer, the oxygen barrier layer including:
binder resin, and
oxygen collecting particles dispersed in the binder resin, the oxygen collecting particles including a first metal oxide that includes a crystal structure consisting of first metal sites and oxygen sites,
wherein the crystal structure is in an oxygen deficiency state.

22. The encapsulation film according to claim 21, wherein the first metal oxide is in a reduced state.

23. The encapsulation film according to claim 21, wherein a bond energy of a first metal-oxygen bond is greater than a bond energy of an oxygen-oxygen bond in an oxygen molecule O₂.

24. The encapsulation film according to claim 23, wherein the bond energy of the first metal-oxygen bond is greater than 498 kJ.

25. The encapsulation film according to claim 21, wherein the first metal oxide includes a cerium oxide represented by Chemical Formula 1:
CeOₓ [Chemical Formula 1]
wherein 1.5<x<2.

26. The encapsulation film according to claim 25,
wherein the first metal oxide is the cerium oxide, and
wherein the crystal structure consists of:
cerium at the first metal sites,
oxygen at the oxygen sites, and
at least one oxygen site being vacant.

27. The encapsulation film according to claim 21, wherein the oxygen barrier layer has a blue color having an ‘x’ value in a range of 0.25 to 0.29 and a ‘y’ value in a range of 0.25 to 0.29, based on CIE 1931 xy color coordinates.

28. The encapsulation film according to claim 27, wherein the oxygen barrier layer is configured to change from the blue color to a white color having the ‘x’ value in a range of 0.31 to 0.35 and the ‘y’ value in the range of 0.32 to 0.36, based on the CIE 1931 xy color coordinates, when the oxygen barrier layer is in contact with oxygen molecule.

29. The encapsulation film according to claim 21, further comprising a moisture barrier layer disposed on the oxygen barrier layer,
wherein the moisture barrier layer includes adhesive resin and absorbent dispersed in the adhesive resin.

30. The encapsulation film according to claim 29,
wherein the absorbent includes a second metal oxide,
the second metal oxide includes a second metal and oxygen, and
a bond energy of a second metal-oxygen bond in the second metal oxide is smaller than a bond energy between an oxygen-oxygen bond in an oxygen molecule.

31. The encapsulation film according to claim 30, wherein the absorbent includes calcium oxide CaO.

32. An encapsulation film comprising:
an adhesive layer; and
an oxygen barrier layer on the adhesive layer, the oxygen barrier layer including:
binder resin, and
oxygen collecting particles dispersed in the binder resin, the oxygen collecting particles including a first metal oxide that includes a crystal structure and that is represented by Chemical Formula 1:
CeOₓ [Chemical Formula 1]
wherein 1.5<<<2.

33. The encapsulation film according to claim 32, wherein in the Chemical Formula 1, 1.55≤x≤1.95.
